(19) United States
(12) Patent Application Publication
(10) Pub. No.: US 2026/0052791 A1
(43) Pub. Date: Feb. 19, 2026

(54) IMAGE SENSOR, IMAGE PROCESSING DEVICE INCLUDING THE IMAGE SENSOR, AND IMAGE PROCESSING METHOD USING THE IMAGE SENSOR

(71) Applicant: SAMSUNG ELECTRONICS CO., LTD., Suwon-si (KR)

(72) Inventors: Sung Hyuk YIM, Suwon-si (KR); Dong Jin PARK, Suwon-si (KR); Jee Hong LEE, Suwon-si (KR); Ju Hyun KO, Suwon-si (KR); Seong Wook SONG, Suwon-si (KR); Sun Young YOO, Suwon-si (KR)

(73) Assignee: SAMSUNG ELECTRONICS CO., LTD., Suwon-si (KR)

(21) Appl. No.: 19/184,593

(22) Filed: Apr. 21, 2025

(30) Foreign Application Priority Data
Aug. 16, 2024 (KR) 10-2024-0109933

(51) Int. Cl. H10F 39/00; H04N 25/78

(52) U.S. Cl. CPC H10F 39/8063; H04N 25/78; H10F 39/802; H10F 39/8053; H10F 39/807

(57) ABSTRACT

An image sensor includes a pixel array including pixel groups having different color filters and a signal processor configured to process image data generated based on pixel signals. Each pixel group includes unit pixel groups. Each unit pixel group includes a first pixel and a second pixel sharing one micro lens. The image data includes image data generated based on pixel signals of a first pixel of a first unit pixel group and a first pixel of a third unit pixel group arranged in a first column and a first pixel of a second unit pixel group and a first pixel of a fourth unit pixel group arranged in a second column. The signal processor is configured to generate image data based on pixel signals of first pixels of the first and third unit pixel groups, excluding pixel signals of first pixels of the second and fourth unit pixel groups.

### CROSS-REFERENCE TO RELATED APPLICATION

This application claims priority from Korean Patent Application No. 10-2024-0109933 filed on Aug. 16, 2024 in the Korean Intellectual Property Office, and all the benefits accruing therefrom under 35 U.S. C. 119, the disclosures of which are herein incorporated by reference in their entireties.

### BACKGROUND

One or more example embodiments of the disclosure relate to an image sensor, an image processing system including the image sensor, and an image processing method using the image sensor, and more specifically, to an image sensor for performing an auto focus function, an image processing system including the image sensor, and an image processing method using the image sensor.

An image sensor that captures an image and converts the captured image into an electrical signal is used not only in general consumer electronic devices such as digital cameras, cameras for mobile phones, and portable camcorders, but also in cameras mounted on automobiles, security devices, and robots. The image sensor has a pixel array, and each of pixels included in the pixel array may include a photodiode. The image sensor may perform an auto focus (AF) function so that the image sensor may perform image capture quickly and accurately.

### SUMMARY

One or more example embodiments of the disclosure provide an image sensor with improved performance and reliability.

One or more example embodiments of the disclosure provide an image processing device with improved performance and reliability.

One or more example embodiments of the disclosure provide an image processing method with improved performance and reliability.

Purposes according to the disclosure are not limited to the above-mentioned purpose. Other purposes and advantages according to the disclosure that are not mentioned may be understood based on following descriptions, and may be more clearly understood based on embodiments according to the disclosure. Further, it will be easily understood that the purposes and advantages according to the disclosure may be realized using mean(s) shown in the claims and any combination thereof.

According to an aspect of an example embodiment of the disclosure, an image sensor includes: a pixel array including a plurality of pixel groups having different color filters, wherein a plurality of micro lenses are respectively arranged in the plurality of pixel groups, wherein each of the plurality of pixel groups includes a plurality of pixels arranged in row and columns; a readout circuit configured to readout a pixel signal output from the pixel array and generate image data based on the readout pixel signal; and a signal processor configured to receive and process the image data, wherein each of the plurality of pixel groups includes a plurality of unit pixel groups, wherein each of the plurality of unit pixel groups includes a first pixel and a second pixel sharing one micro lens of the plurality of micro lenses, wherein the image data includes: first image data generated based on pixel signals of respective first pixels and respective second pixels of the plurality of unit pixel groups; and second image data generated based on pixel signals of the respective first pixels of the plurality of unit pixel groups, wherein the respective first pixels of the plurality of unit pixel groups include: a first pixel of a first unit pixel group and a first pixel of a third unit pixel group arranged in a first column and including different micro lenses; and a first pixel of a second unit pixel group and a first pixel of a fourth unit pixel group arranged in a second column and including different micro lenses, and wherein the signal processor is configured to generate third image data based on pixel signals of first pixels of the first unit pixel group and the third unit pixel group, excluding pixel signals of first pixels of the second unit pixel group and the fourth unit pixel group.

According to an aspect of an example embodiment of the disclosure, an image sensor includes: a first pixel group having a first color filter, a second pixel group having a second color filter, a third pixel group having a third color filter, and a fourth pixel group having a fourth color filter, wherein each of the first to the fourth pixel groups includes a plurality of pixels arranged in a first direction and a second direction intersecting the first direction, wherein each of the first to the fourth pixel groups includes a plurality of unit pixel groups; a readout circuit configured to readout pixel signals output from the plurality of pixels and generate pixel data based on the pixel signals; a signal processor configured to receive and process the pixel data; first partitioning wall structures and second partitioning wall structures disposed in a peripheral area of each of the first to the fourth pixel groups, wherein the first and the second partitioning wall structures extend in the first direction and are spaced apart from each other in the second direction in a plan view of the image sensor; and third partitioning wall structures disposed between adjacent ones of the plurality of unit pixel groups included in each of the first to the fourth pixel groups, and extending in the first direction in the plan view of the image sensor, wherein the first pixel group includes first pixels adjacent to a first partitioning wall structure and arranged in the first direction in the plan view of the image sensor, wherein the second pixel group includes first pixels adjacent to a second partitioning wall structure and arranged in the first direction in the plan view of the image sensor, wherein a height of the first partitioning wall structure and a height of the second partitioning wall structure are different from a height of a third partitioning wall structure, and wherein the signal processor is configured to generate first image data obtained by sampling pixel data corresponding to the first pixels of the first pixel group and the first pixels of the second pixel group.

According to an aspect of an example embodiment of the disclosure, an image processing device includes: a pixel array including a plurality of pixel groups having different color filters, wherein each of the plurality of pixel groups includes a plurality of pixels arranged in a first direction and a second direction intersecting the first direction; a readout circuit configured to readout a pixel signal output from the pixel array and generate image data based on the readout pixel signal; a signal processor configured to generate first image data and second image data sampled based on the image data; and a processor configured to receive data on a phase difference, which is based on the first image data and the second image data, from the signal processor, wherein each of the plurality of pixel groups includes a plurality of unit pixel groups, wherein each of the plurality of unit pixel groups includes a first pixel and a second pixel sharing one micro lens, wherein the image data includes: full image data generated based on pixel signals of first pixels and second pixels of the plurality of unit pixel groups; and third image data generated based on pixel signals of the first pixels of the plurality of unit pixel groups, wherein the first pixels of the plurality of unit pixel groups include: a first pixel of a first unit pixel group and a first pixel of a third unit pixel group arranged in a first column and including different micro lenses; and a first pixel of a second unit pixel group and a first pixel of a fourth unit pixel group arranged in a second column and including different micro lenses, and wherein the signal processor is configured to generate the first image data based on pixel signals of the first pixels of the first unit pixel group and the third unit pixel group, excluding pixel signals of the first pixels of the second unit pixel group and the fourth unit pixel group.

According to an aspect of an example embodiment of the disclosure, an image processing method incudes providing a first chip including a first pixel group having a first color filter, a second pixel group having a second color filter, a third pixel group having a third color filter, and a fourth pixel group having a fourth color filter, wherein each of the first to the fourth pixel groups includes a plurality of pixels arranged in a first direction and a second direction intersecting the first direction, wherein the first chip includes first partitioning wall structures and second partitioning wall structures disposed in a peripheral area of each of the first to the fourth pixel groups, wherein the first and the second partitioning wall structures extend in the first direction and are spaced apart from each other in the second direction in a plan view of the image sensor, wherein the first and the second partitioning wall structures are absent between adjacent ones of the pixels in each of the first to fourth pixel groups; reading out a pixel signal output from the first chip and generating pixel data based on the pixel signal; and generating first image data and second image data sampled based on the pixel data, wherein the generating the first image data includes sampling pixel data corresponding to pixels adjacent to the first partitioning wall structures and pixel data corresponding to pixels adjacent to the second partitioning wall structures.

### BRIEF DESCRIPTION OF DRAWINGS

The above and other aspects and features of the disclosure will become more apparent by describing in detail example embodiments thereof with reference to the attached drawings, in which:

FIG. 1 is a block diagram showing an image processing system according to one or more example embodiments;

FIG. 2 is a block diagram showing a configuration of an image sensor according to one or more example embodiments;

FIG. 3 is a diagram for illustrating a pixel array of an image sensor according to one or more example embodiments;

FIG. 4 is an example circuit diagram of a first pixel group of FIG. 3;

FIG. 5 is a cross-sectional view taken along a line A-A′ of FIG. 3;

FIG. 6 is a diagram for illustrating an image sensor according to one or more example embodiments, and is a diagram corresponding to FIG. 5;

FIG. 7 is a timing diagram for illustrating an operation of an image sensor according to one or more example embodiments;

FIGS. 8 to 11 are diagrams for illustrating a configuration and an operation of a signal processor of an image sensor according to one or more example embodiments;

FIGS. 12 to 14 are diagrams for illustrating a configuration and an operation of a signal processor of an image sensor according to one or more example embodiments;

FIG. 15 is a diagram for illustrating a pixel array of an image sensor according to one or more example embodiments;

FIG. 16 is an example circuit diagram of a first pixel group of FIG. 15.

FIG. 17 is a cross-sectional view taken along a line B-B′ of FIG. 15;

FIG. 18 is a diagram for illustrating an image sensor according to one or more example embodiments, and is a diagram corresponding to FIG. 17;

FIG. 19 is a timing diagram for illustrating an operation of an image sensor according to one or more example embodiments;

FIGS. 20 to 23 are diagrams for illustrating a configuration and an operation of a signal processor of an image sensor according to one or more example embodiments; and

FIG. 24 is a schematic diagram showing an image sensor according to one or more example embodiments.

### DETAILED DESCRIPTION

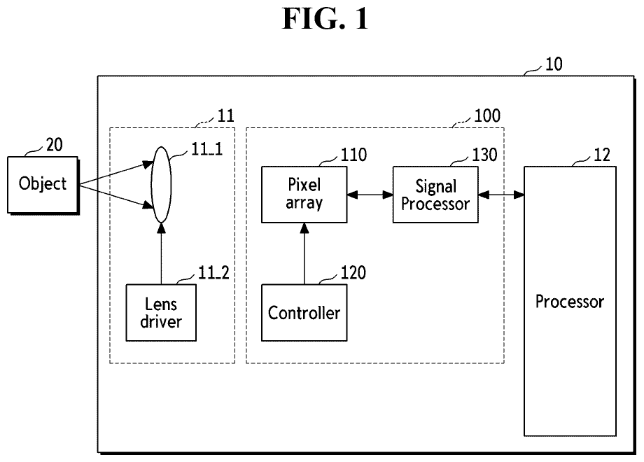

Hereinafter, in order to describe the disclosure more specifically, the attached drawings according to one or more example embodiments of the disclosure will be described in more detail. With reference to FIGS. 1 to 11, an image sensor according to one or more example embodiments will be described.

FIG. 1 is a block diagram showing an image processing system according to one or more example embodiments. FIG. 1 is a diagram for illustrating an image processing system 10 that performs an auto-focus (AF) function.

The image processing system 10 according to one or more example embodiments may include an imaging unit 11, an image sensor 100, and a processor 12.

The image processing system 10 may be equipped with a focus detection function. The image sensor 100 and the imaging unit 11 may be components included in a camera module.

The image processing system 10 may be embodied as an electronic device that captures an image, displays the captured image, and/or performs an operation based on the captured image. The image processing system 10 may be embodied as, for example but not limited to, a personal computer (PC), an Internet of Things (IoT) device, or a portable electronic device. The portable electronic device may include a laptop computer, a mobile phone, a smart phone, a tablet PC, a personal digital assistant (PDA), an enterprise digital assistant (EDA), a digital still camera, a digital video camera, an audio device, a portable multimedia player (PMP), a personal navigation device (PND), an MP3 player, a handheld game console, an e-book, a wearable device, etc. Furthermore, the image processing system 10 may be mounted on drones, electronic devices such as advanced drivers assistance systems (ADAS), or electronic devices provided as components in vehicles, furniture, manufacturing equipment, doors, and various measuring devices.

The image processing system 10 may further include other components such as a display and a user interface. The image processing system 10 may be embodied in a system on chip (SoC) manner.

An overall operation of the image processing system 10 may be controlled by the processor 12. The processor 12 may provide a control signal for an operation of each of the components such as a lens driver 11_2 and a controller 120 to corresponding components. For example, the imaging unit 11 may further include an aperture driver for driving an aperture, and the processor 12 may provide a control signal for controlling the aperture driver. In one or more example embodiments, the processor 12 may be an application processor (AP).

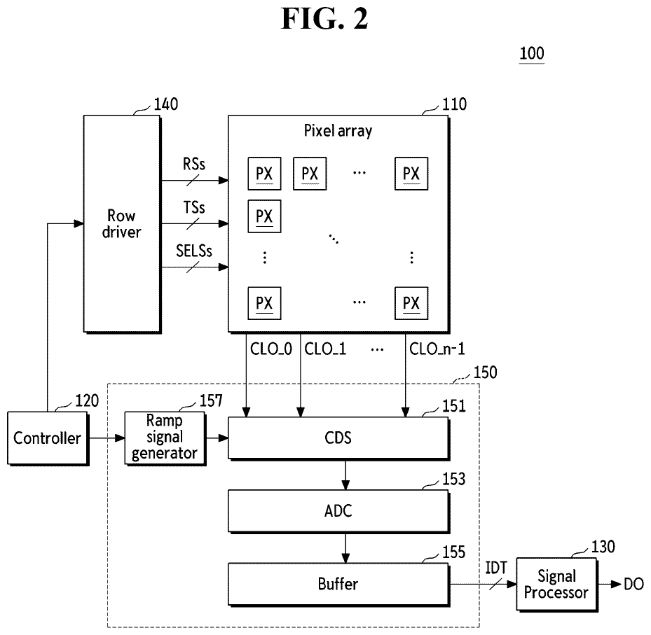

The imaging unit 11 may be a component that receives light and may include an optical lens 11_1 and a lens driver 11_2. The optical lens 11_1 may have a plurality of lenses. The image sensor 100 may convert an optical signal reflected from an object 20 through the optical lens 11_1 into an electrical signal and generate image data (e.g., IDT of FIG. 2) based on the electrical signal. In FIG. 1, the optical lens 11_1 is illustrated as including one lens. However, the disclosure is not limited thereto. The optical lens 11_1 may include a plurality of lenses.

The lens driver 11_2 may communicate information about focus detection with the processor 12, and may adjust a position of the optical lens 11_1 according to the control signal provided from the processor 12. The lens driver 11_2 may move the optical lens 11_1 in a direction in which a distance thereof to the object 20 increases or decreases, and accordingly, the distance between the optical lens 11_1 and the object 20 may be adjusted. Depending on the position of the optical lens 11_1, the object 20 may be in focus or blurred.

For example, when the distance between the optical lens 11_1 and the object 20 is relatively smaller, the optical lens 11_1 may be out of an in-focus position at which image processing system 10 focuses on the object 20, and thus a difference between phases of images captured by the image sensor 100 may occur. The lens driver 11_2 may move the optical lens 11_1 in a direction in which the distance thereof to the object 20 increases based on the control signal provided from the processor 12. Conversely, when the distance between the optical lens 11_1 and the object 20 is relatively larger, the optical lens 11_1 may be out of the in-focus position, and thus a difference between phases of the images formed on the image sensor 100 may occur. The lens driver 11_2 may move the optical lens 11_1 in a direction in which the distance thereof to the object 20 decreases based on the control signal provided from the processor 12.

The image sensor 100 may convert incident light thereto into an image signal. The image sensor 100 may include a pixel array 110, the controller 120, and a signal processor 130. The optical signal having transmitted through the optical lens 11_1 may reach a light-receiving surface of the pixel array 110 to form an image of the object 20.

The pixel array 110 may be a complementary metal oxide semiconductor image sensor (CMOSIS) that converts an optical signal into an electrical signal. Such a pixel array 110 may be controlled by the controller 120. The pixel array 110 may include a plurality of pixels that convert an optical signal into an electrical signal. Each of the plurality of pixels may generate a pixel signal according to an intensity of the detected light.

The image sensor 100 may provide output data (e.g., DO of FIG. 2) to the processor 12. The output data (e.g., DO of FIG. 2) may include phase difference data including phase difference information, and/or may include image data including phase information such that the processor 12 may perform a phase difference calculation. The phase difference may be based on image data generated by the signal processor 130, which will be described later.

The processor 12 may perform signal processing for reducing noise on input data and improving image quality, such as gamma correction, color filter array interpolation, color matrix, color correction, and color enhancement. Furthermore, the processor 12 may compress the image data generated by performing signal processing for improving image quality to generate an image file, or reconstruct the image data from the image file.

FIG. 2 is a block diagram showing a configuration of an image sensor according to one or more example embodiments.

Referring to FIG. 2, the image sensor 100 may include the pixel array 110, the controller 120, the image signal processor 130, a row driver 140, and a readout circuit 150. The readout circuit 150 may include a correlated double sampling (hereinafter, CDS) 151, an analog-to-digital converter (hereinafter, ADC) 153, and a buffer 155.

The pixel array 110 may convert an optical signal into an electrical signal and may include a plurality of pixels PX arranged two-dimensionally. Each of the plurality of pixels PX may generate a pixel signal according to an intensity of the detected light. The pixel PX may be embodied using a photoelectric conversion element such as a charge coupled device (CCD) or a complementary metal oxide semiconductor (CMOS), or may also be embodied using various types of photoelectric conversion elements. The pixel array 110 may include a color filter to sense various colors, and each of the plurality of pixels PX may sense a corresponding color. Accordingly, the image sensor 100 may generate image data including color information.

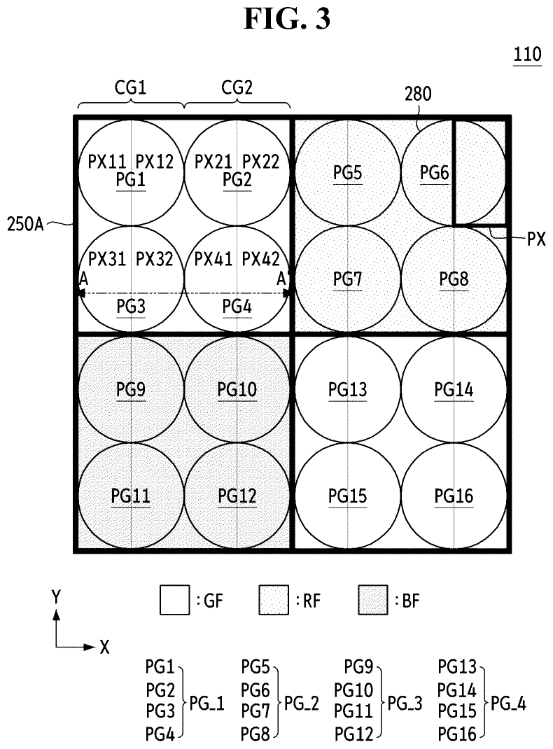

In one or more example embodiments, the pixel array 110 may include a plurality of pixels PX arranged along rows and columns. An example of a configuration of the pixel array 110 is described later with reference to FIG. 3.

Each of the plurality of pixels PX may output a pixel signal to the CDS 151 through a corresponding one of first to n-th column output lines CLO_0 to CLO_n-1. The CDS 151 may sample and hold the pixel signal provided from the pixel array 110. The CDS 151 may double sample a level of a specific noise (or a reset level) and a level according to an image signal (or an image level), and output a level corresponding to a difference therebetween. Furthermore, the CDS 151 may receive a ramp signal generated by the ramp signal generator 157, compare the ramp signal and the pixel signal with each other, and output the comparison result.

The analog-to-digital converter 153 may convert an analog signal corresponding to the level received from the CDS 151 into a digital signal. The buffer 155 may latch the digital signal, and the latched digital signal may be sequentially output as the image data IDT to the signal processor 130 or to an outside of the image sensor 100. In one or more example embodiments, the image data IDT may be referred to as pixel data.

The controller 120 may control the row driver 140 to cause the pixel array 110 to absorb light and accumulate charges therein, or to temporarily store the accumulated charges therein, and to output an electrical signal according to the stored charges to an external element to the pixel array 110. Furthermore, the controller 120 may control the readout circuit 150 to measure a level of the pixel signal provided by the pixel array 110.

The row driver 140 may generate a reset control signal RS, a transfer control signal TS, and a select signal SELS for controlling the pixel array 110 and provide the generated signals to the plurality of pixels PX. The row driver 140 may determine activation and deactivation timings of the reset control signal RS, the transfer control signal TS, and the select signal SELS to be provided to the plurality of pixels PX.

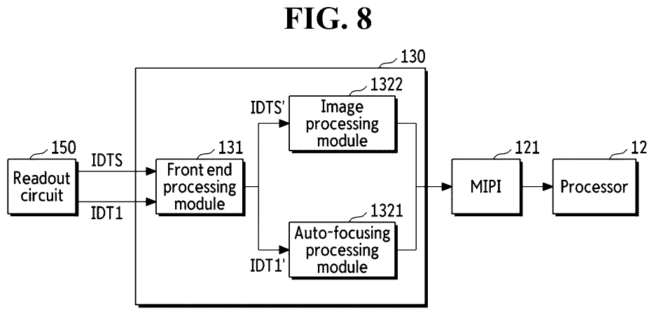

The signal processor 130 may perform signal processing on the image data IDT provided from the readout circuit 150. An example of a configuration and an operation of the signal processor 130 will be described later with reference to FIGS. 8 to 11.

FIG. 3 is a diagram for illustrating a pixel array of an image sensor according to one or more example embodiments. For reference, FIG. 3 shows an example of a portion of the pixel array 110 of FIG. 2.

Referring to FIG. 3, the pixel array 110 may include a plurality of pixel groups PG_1 to PG_4. For example, the plurality of pixel groups PG_1 to PG_4 may include first to fourth pixel groups PG_1 to PG_4 including one of first to third color filters GF, RF, and BF.

The first to fourth pixel groups PG_1 to PG_4 may include a plurality of unit pixel groups PG1 to PG16. For example, the first to fourth pixel groups PG_1 to PG_4 may include first to sixteenth unit pixel groups PG1 to PG16.

For example, the first pixel group PG_1 may include the first to fourth unit pixel groups PG1 to PG4. The second pixel group PG_2 may include the fifth to eighth unit pixel groups PG5 to PG8. The third pixel group PG_3 may include the ninth to twelfth unit pixel groups PG9 to PG12. The fourth pixel group PG_4 may include the thirteenth to sixteenth unit pixel groups PG13 to PG16.

For example, the first and third unit pixel groups PG1 and PG3 may be arranged in a first column group CG1, and the second and fourth unit pixel groups PG2 and PG4 may be arranged in a second column group CG2. For example, the ninth and eleventh unit pixel groups PG9 and PG11 may be arranged in the first column group CG1, and the tenth and twelfth unit pixel groups PG10 and PG12 may be arranged in the second column group CG2.

Furthermore, for example, the fifth and seventh unit pixel groups PG5 and PG7 may be arranged in the same column group, and the sixth and eighth unit pixel groups PG6 and PG8 may be arranged in the same column group. For example, the thirteenth and fifteenth unit pixel groups PG13 and PG15 and the fifth and seventh unit pixel groups PG5 and PG7 may be arranged in the same column group. The fourteenth and sixteenth unit pixel groups PG14 and PG16 and the sixth and eighth unit pixel groups PG6 and PG8 may be arranged in the same column group.

The pixel array 110 may include the plurality of pixels PX arranged along a first direction X and a second direction Y intersecting the first direction X. Each of the first to sixteenth unit pixel groups PG1 to PG16 may include two pixels PX sharing one micro lens 280. Furthermore, the first to sixteenth unit pixel groups PG1 to PG16 may include 16 different micro lenses 280, respectively. Each of all of the plurality of pixels PX included in the pixel array 110 may be capable of performing the AF function.

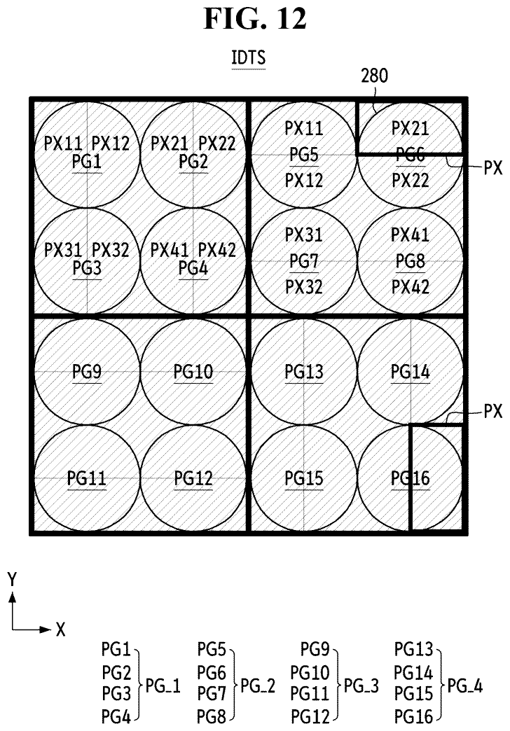

In the first to fourth pixel groups PG_1 to PG_4, two pixels PX sharing one micro lens 280 may be arranged adjacently to each other in the first direction X. However, the disclosure is not limited thereto, and the arrangement directions of the pixels in the pixel groups may be different from each other as described later with reference to FIG. 12.

A first partitioning wall structure 250A may be disposed between adjacent ones of the first to fourth pixel groups PG_1 to PG_4 in a plan view. The first partitioning wall structure 250A may be disposed on a perimeter of each of the first to fourth pixel groups PG_1 to PG_4 in a plan view. The first partitioning wall structure 250A may surround each of the first to fourth pixel groups PG_1 to PG_4 in a plan view.

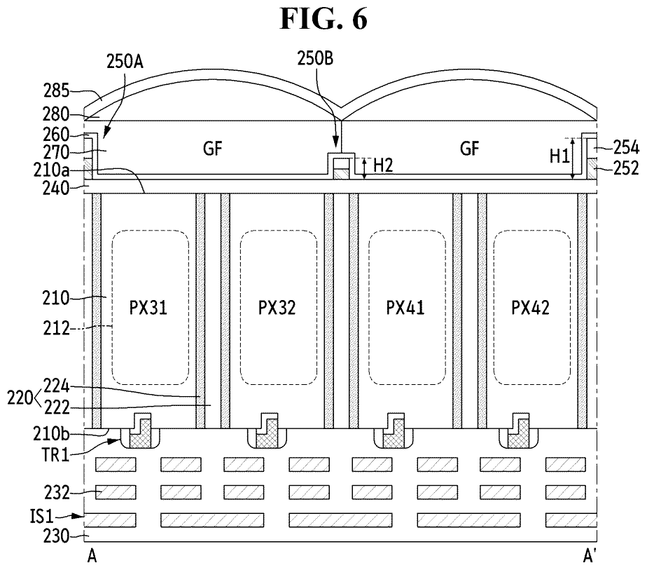

In a plan view, the partitioning wall structure may not be disposed between the first to fourth unit pixel groups PG1 to PG4, between the fifth to eighth unit pixel groups PG5 to PG8, between the ninth to twelfth unit pixel groups PG9 to PG12, and between the thirteenth to sixteenth unit pixel groups PG13 to PG16. However, the disclosure is not limited thereto, and a second partitioning wall structure 250B may be disposed therebetween as described later with reference to FIG. 6.

The first partitioning wall structure 250A may include a plurality of first partitioning wall structures 250A extending in the second direction Y and spaced apart from each other in the first direction X in a plan view. In this case, the first and third unit pixel groups PG1 and PG3 of the first pixel group PG_1 may be adjacent to one of the plurality of first partitioning wall structures 250A. Furthermore, the fifth and seventh unit pixel groups PG5 and PG7 of the second pixel group PG_2 may be adjacent to another of the plurality of the first partitioning wall structures 250A.

Similarly, the ninth and eleventh unit pixel groups PG9 and PG11 of the third pixel group PG_3 may be adjacent to further one of the plurality of the first partitioning wall structures 250A. Furthermore, the thirteenth and fifteenth unit pixel groups PG13 and PG15 of the fourth pixel group PG_4 may be adjacent to still further one of the plurality of the first partitioning wall structures 250A.

In one or more example embodiments, the partitioning wall structure may be referred to as a grid pattern.

The pixel array 110 may include a color filter to sense various colors. Each of the first to sixteenth unit pixel groups PG1 to PG16 may include one of a green color filter GF, a red color filter RF, and a blue color filter BF. In one or more example embodiments, an area ratio of the red color filter RF, the green color filter GF, and the blue color filter BF in the pixel array 110 may be 1:2:1. However, the disclosure is not limited thereto.

In one or more example embodiments, four unit pixel groups arranged adjacently to each other among the plurality of unit pixel groups (for example, the first to sixteenth unit pixel groups PG1 to PG16) included in the pixel array 110 may include the same color filter. The color filters may be disposed on a basis of four unit pixel groups among the first to sixteenth unit pixel groups PG1 to PG16.

For example, the first pixel group PG_1 may include the green color filter GF, the second pixel group PG_2 may include the red color filter RF, the third pixel group PG_3 may include the blue color filter BF, and the fourth pixel group PG_4 may include the green color filter GF. However, the disclosure is not limited thereto, and each of the first to sixteenth pixel groups PG1 to PG16 may include at least one of a yellow color filter, a cyan color filter, and a magenta color filter.

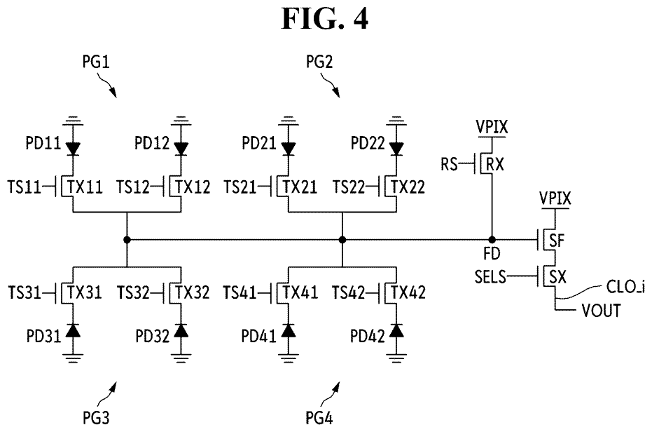

FIG. 4 is an example circuit diagram of the first pixel group of FIG. 3. The description of the first pixel group PG_1 may be similarly applied to each of the second to fourth pixel groups PG_2 to PG_4.

FIG. 4 illustrates an embodiment in which pixels included in the first to fourth unit pixel groups PG1 to PG4 share a floating diffusion area FD. However, the disclosure is not limited thereto.

Referring to FIG. 3 and FIG. 4, a first pixel PX11 of the first unit pixel group PG1 may include a first photo diode PD11 and a first transfer transistor TX11, and a second pixel PX12 of the first unit pixel group PG1 may include a second photo diode PD12 and a second transfer transistor TX12.

A first pixel PX21 of the second unit pixel group PG2 may include a first photo diode PD21 and a first transfer transistor TX21, and a second pixel PX22 of the second unit pixel group PG2 may include a second photo diode PD22 and a second transfer transistor TX22.

A first pixel PX31 of the third unit pixel group PG3 may include a first photo diode PD31 and a first transfer transistor TX31, and a second pixel PX32 of the third unit pixel group PG3 may include a second photo diode PD32 and a second transfer transistor TX32.

A first pixel PX41 of the fourth unit pixel group PG4 may include a first photo diode PD41 and a first transfer transistor TX41, and a second pixel PX42 of the fourth unit pixel group PG4 may include a second photo diode PD42 and a second transfer transistor TX42.

Each of the first and second photodiodes PD11 and PD12 of the first unit pixel group PG1, the first and second photodiodes PD21 and PD22 of the second unit pixel group PG2, the first and second photodiodes PD31 and PD32 of the third unit pixel group PG3, and the first and second photodiodes PD41 and PD42 of the fourth unit pixel group PG4 may be embodied as a photoelectric conversion element that generates a photoelectric charge that varies depending on an intensity of detected light.

For example, each of the first and second photodiodes PD11 and PD12 of the first unit pixel group PG1, each of the first and second photodiodes PD21 and PD22 of the second unit pixel group PG2, each of the first and second photodiodes PD31 and PD32 of the third unit pixel group PG3, and each of the first and second photodiodes PD41 and PD42 of the fourth unit pixel group PG4 may be embodied as a P-N junction diode and may generate the charges, that is, electrons as negative charges, and holes as positive charges in proportion to an amount of incident light thereto.

Each of the first and second transfer transistors TX11 and TX12 of the first unit pixel group PG1 may transfer the generated photocharges to the floating diffusion area FD in response to a corresponding transfer control signal (e.g., one of TS11 and TS12). Each of the first and second transfer transistors TX21 and TX22 of the second unit pixel group PG2 may transfer the generated photocharges to the floating diffusion area FD in response to a corresponding transfer control signal (e.g., one of TS21 and TS22). Each of the first and second transfer transistors TX31 and TX32 of the third unit pixel group PG3 may transfer the generated photocharges to the floating diffusion area FD in response to a corresponding transfer control signal (e.g., one of TS31 and TS32). Each of the first and second transfer transistors TX41 and TX42 of the fourth unit pixel group PG4 may transfer the generated photocharges to the floating diffusion area FD in response to a corresponding transfer control signal (e.g., one of TS41 and TS42).

The first to fourth unit pixel groups PG1 to PG4 may share the floating diffusion area FD, a select transistor SX, a source follower SF, and a reset transistor RX with each other. However, in an embodiment, unlike as shown in FIG. 4, at least one of the select transistor SX, the source follower SF, and the reset transistor RX may be omitted. The pixels included in the first to fourth unit pixel groups PG1 to PG4 may output a pixel signal VOUT to the same column output line CL0_i. In this regard, an i-th column output line CLO_i (where i is an integer greater than or equal to 0 and smaller than n-1) may be, for example, one of first to n-th column output lines CLO_0 to CLO_n-1 of FIG. 2.

The reset transistor RX may periodically reset charges accumulated in the floating diffusion area FD. A source electrode of the reset transistor RX may be electrically connected to the floating diffusion area FD, and a drain electrode thereof may be electrically connected to a power supply voltage VPIX. When the reset transistor RX is turned on according to the reset control signal RS, the power supply voltage VPIX electrically connected to the drain electrode of the reset transistor RX may be transferred to the floating diffusion area FD. When the reset transistor RX is turned on, the charges accumulated in the floating diffusion area FD may be discharged therefrom, such that the floating diffusion area FD may be reset.

The source follower SF may be controlled based on an amount of photocharges accumulated in the floating diffusion area FD. The source follower SF may act as a buffer amplifier which may buffer a signal based on the charges charged in the floating diffusion area FD. The source follower SF may amplify potential change in the floating diffusion area FD and output the amplified potential change as the pixel signal VOUT to the i-th column output line CLO_i.

A drain electrode of the select transistor SX may be electrically connected to a source electrode of the source follower SF. The select transistor SX may output the pixel signal VOUT to the CDS (e.g., 151 in FIG. 2) via the column output line, in response to the select signal SELS.

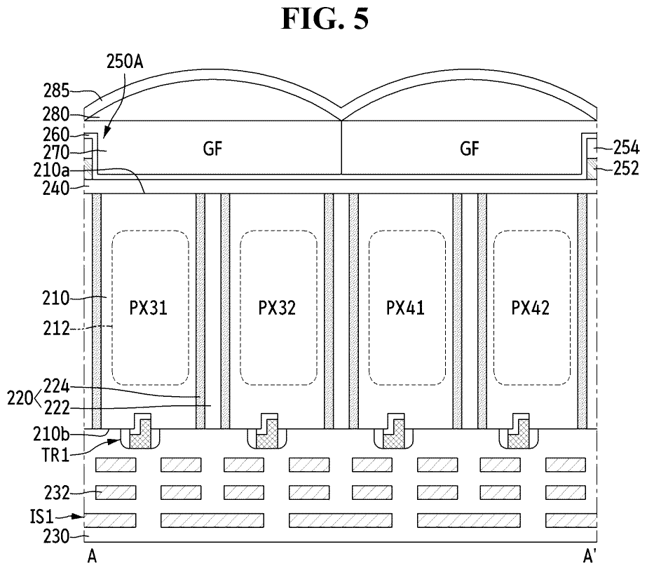

FIG. 5 is a cross-sectional view taken along a line A-A′ of FIG. 3.

An image sensor according to one or more example embodiments may include a first substrate 210, a photoelectric conversion layer 212, a first pixel isolation pattern 220, a first electronic element TR1, a first wiring structure IS1, a surface insulating film 240, a color filter 270, a first grid pattern 250A, and a micro lens 280.

The first substrate 210 may be a semiconductor substrate. For example, the first substrate 210 may include bulk silicon or a silicon-on-insulator (SOI). The first substrate 210 may be a silicon substrate, or may include a material other than silicon such as, for example but not limited to, silicon germanium, indium antimonide, lead telluride compound, indium arsenide, indium phosphide, gallium arsenide, or gallium antimonide. Alternatively, the first substrate 210 may include a base substrate and an epi layer formed on the base substrate.

The first substrate 210 may include a first surface 210a and a second surface 210b that are opposite to each other. The first surface 210a may mean a back surface of the first substrate 210, and the second surface 210b may mean a front surface of the first substrate 210. In one or more example embodiments, the first surface 210a of the first substrate 210 may be a light-receiving surface on which light is incident. That is, the image sensor according to one or more example embodiments may be a back-side illuminated (BSI) image sensor.

The photoelectric conversion layer 212 may be provided within the first substrate 210.

A plurality of photoelectric conversion layers 212 may be arranged to correspond to respective pixels (e.g., PX in FIG. 3). For example, the photoelectric conversion layers 212 may be arranged two-dimensionally (e.g., in a matrix form) on a plane including the first direction X and the second direction Y. Each of the photoelectric conversion layers 212 may be disposed within each pixel PX in FIG. 3. The photoelectric conversion layer 212 may generate the charges in proportion to an amount of light incident from the outside.

The photoelectric conversion layer 212 may be formed by doping an impurity within the first substrate 210. For example, the photoelectric conversion layer 212 may be formed by ion-injecting an n-type impurity into the first substrate 210 of a p-type.

The photoelectric conversion layer 212 may include, but is not limited to, at least one of a photo diode, a photo transistor, a photo gate, a pinned photo diode, an organic photo diode, a quantum dot, or any combination thereof.

The first pixel isolation pattern 220 may be formed within the first substrate 210. The first pixel isolation pattern 220 may define the pixels (e.g., PX in FIG. 3) within the first substrate 210. For example, the first pixel isolation pattern 220 may be formed in a grid shape in a plan view, and may surround each of the pixels (e.g., PX in FIG. 3) arranged in a matrix shape. In one or more example embodiments, the first pixel isolation pattern 220 may extend within the first substrate 210.

In one or more example embodiments, the first pixel isolation pattern 220 may include a conductive filling pattern 222 and an insulating spacer film 224. The conductive filling pattern 222 may extend within the first substrate 210, and the insulating spacer film 224 may be positioned between the conductive filling pattern 222 and the first substrate 210.

For example, an isolation trench defining each of pixels (e.g., PX in FIG. 3) may be formed within the first substrate 210. The insulating spacer film 224 may extend along a side surface of the isolation trench. The conductive filling pattern 222 may be formed on the insulating spacer film 224 to fill a remaining area of the isolation trench. The insulating spacer film 224 may electrically insulate the conductive filling pattern 222 from the first substrate 210. The conductive filling pattern 222 may include, but is not limited to, polysilicon poly (Si), for example. The insulating spacer film 1224 may include, but is not limited to, at least one of silicon oxide, aluminum oxide, tantalum oxide, or any combination thereof, for example.

The first electronic element TR1 may be formed on the second surface 210b of the first substrate 210. The first electronic element TR1 may include various transistors for processing electrical signals generated from the pixels (e.g., PX in FIG. 3). For example, the first electronic element TR1 may include transistors such as a transfer transistor, a reset transistor, a source follower transistor, or a select transistor.

The first wiring structure IS1 may be formed on the second surface 210b of the first substrate 210. The first wiring structure IS1 may include one or a plurality of wirings. For example, the first wiring structure IS1 may include a first inter-wiring insulating film 230 and a plurality of first wirings 232 within the first inter-wiring insulating film 230. In FIG. 5, a number of layers and an arrangement of wirings included in the first wiring structure IS1 are merely examples, and the disclosure is not limited thereto.

In one or more example embodiments, the first wiring 232 may be electrically connected to the pixels (e.g., PX in FIG. 3). For example, the first wiring 232 may be in contact with the first electronic element TR1. The surface insulating film 240 may be formed on the first surface 210a of the first substrate 210. The surface insulating film 240 may extend along the first surface 210a of the first substrate 210. The surface insulating film 240 may include, but is not limited to, at least one of silicon oxide, silicon nitride, silicon oxynitride, aluminum oxide, hafnium oxide, or any combination thereof. For example, the surface insulating film 240 may function as an anti-reflection film to prevent reflection of light incident on the first substrate 210.

The color filter 270 may be formed on the first surface 210a of the first substrate 210. For example, the color filter 270 may be formed on the surface insulating film 240. A plurality of color filters 270 may be arranged two-dimensionally (for example, in a matrix form) on a plane including the first direction X and the second direction Y. Referring to FIG. 3 and FIG. 5, the green color filter GF may be disposed on pixels PX31, PX32, PX41, and PX42 of the third and fourth unit pixel groups PG3 and PG4.

The first grid pattern 250A may be formed on the first surface 210a of the first substrate 210. For example, the first grid pattern 250A may be formed on the surface insulating film 240. The first grid pattern 250A may mean a light-shielding pattern. However, the disclosure is not limited thereto.

The first grid pattern 250A may be disposed on a perimeter of each of the first to fourth pixel groups (e.g., PG_1 to PG_4 in FIG. 3) in a plan view. The first grid pattern 250A may surround each of the first to fourth pixel groups (e.g., PG_1 to PG_4 in FIG. 3) in a plan view. Referring to FIG. 3 and FIG. 5, the first grid pattern 250A may surround the green color filter GF disposed on the pixels (e.g., PX of FIG. 3). Accordingly, the green color filter GF corresponding to one pixel group may be isolated from an adjacent color filter 270 via the first grid pattern 250A.

In one or more example embodiments, the first grid pattern 250A may be disposed between color filters 270 adjacent to each other and having the different colors, and may not be disposed between color filters 270 adjacent to each other and having the same color.

In one or more example embodiments, the first grid pattern 250A may extend through a portion of the color filter 270, and a vertical level of an upper surface of the first grid pattern 250A may be lower than a vertical level of an upper surface of the color filter 270. Alternatively, the first grid pattern 250A may extend through the color filter 270 such that the upper surface of the first grid pattern 250A is substantially coplanar with the upper surface of the color filter 270.

In one or more example embodiments, the first grid pattern 250A may include a metal pattern 252 and a low refractive index pattern 254. The metal pattern 252 and the low refractive index pattern 254 may be sequentially stacked on the surface insulating film 240.

The metal pattern 252 may include, but is not limited to, at least one of titanium (Ti), titanium nitride (TiN), tantalum (Ta), tantalum nitride (TaN), tungsten (W), aluminum (Al), copper (Cu), or any combination thereof. The low refractive index pattern 254 may include a low refractive index material having a lower refractive index than that of silicon (Si). For example, the low refractive index pattern 254 may include at least one of silicon oxide, aluminum oxide, tantalum oxide, or a combination thereof. However, the disclosure is not limited thereto.

In one or more example embodiments, a first protective film 260 may be provided on the surface insulating film 240 and the first grid pattern 250A. For example, the first protective film 260 may conformally extend along a profile of an upper surface of the surface insulating film 240, and a side surface and the upper surface of the first grid pattern 250A. The first protective film 260 may be interposed between the surface insulating film 240 and the color filter 270 and between the first grid pattern 250A and the color filter 270. The first protective film 260 may prevent damage to the surface insulating film 240 and the first grid pattern 250A. The first protective film 260 may include, but is not limited to, aluminum oxide, for example.

The micro lens 280 may be provided on the first surface 210a of the first substrate 210. For example, the micro lens 280 may be provided on the color filters 270. For example, a plurality of micro lenses 280 may be arranged two-dimensionally (for example, in a matrix form) on a plane including the first direction X and the second direction Y.

The plurality of micro lenses 280 may be arranged such that each of the plurality of micro lenses 280 may correspond to each of the first to fourth unit pixel groups (PG1 to PG4 in FIG. 3).

The micro lens 280 may have a convex shape and may have a predetermined radius of curvature. Accordingly, the micro lens 280 may condense light incident on the photoelectric conversion layer 212. The micro lens 280 may include, for example, a light-transmissive resin. However, the disclosure is not limited thereto.

In one or more example embodiments, a second protective film 285 may be provided on the micro lens 280. The second protective film 285 may extend along a surface of the micro lens 280. The second protective film 285 may include an inorganic oxide. For example, the second protective film 285 may include at least one of silicon oxide, titanium oxide, zirconium oxide, hafnium oxide, or any combination thereof. However, the disclosure is not limited thereto. For example, the second protective film 285 may include a low temperature oxide (LTO).

FIG. 6 is a diagram for illustrating an image sensor according to one or more example embodiments, and is a diagram corresponding to FIG. 5. For convenience of description, contents duplicate with those as described above with reference to FIGS. 1 to 5 are briefly described or descriptions thereof are omitted. The description about the first grid pattern 250A as set forth above with reference to FIG. 5 may be equally applied to the first grid pattern 250A of FIG. 6.

Referring to FIG. 3 and FIG. 6, the image sensor according to one or more example embodiments may further include a second grid pattern 250B disposed between the third unit pixel group (e.g., PG3 of FIG. 3) and the fourth unit pixel group (e.g., PG4 of FIG. 3). The second grid pattern 250B may be disposed between adjacent ones of the first to fourth unit pixel groups PG1 to PG4 of FIG. 3 in the plan view. The second grid pattern 250B may extend in the second direction Y in the plan view.

The second grid pattern 250B may isolate the green color filter GF disposed on the first and second pixels PX31 and PX32 of the third unit pixel group (e.g., PG3 in FIG. 3) from the green color filter GF disposed on the first and second pixels PX41 and PX42 of the fourth unit pixel group (e.g., PG4 in FIG. 3).

In a height direction perpendicular to the plane including the first and second directions X and Y, a height H2 of the second grid pattern 250B may be different from a height H1 of the first grid pattern 250A. For example, based on the height direction perpendicular to the first and second directions X, Y, the height H2 of the second grid pattern 250B may be smaller than the height H1 of the first grid pattern 250A.

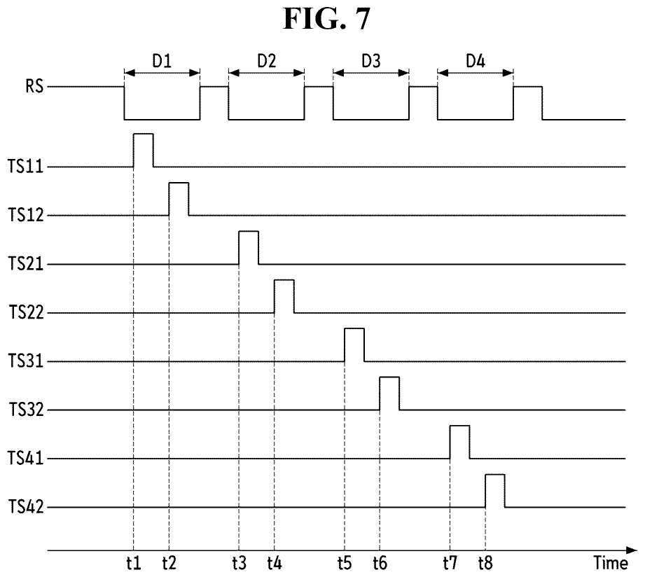

FIG. 7 is a timing diagram for illustrating an operation of an image sensor according to one or more example embodiments. For reference, FIG. 7 is a diagram for illustrating a first operation mode in which the image sensor outputs a sum (or an average) of output values of the pixels as a sensing voltage.

Referring to FIG. 7, the reset transistor RX may be turned on based on the reset control signal RS to reset a voltage of the floating diffusion area FD. When the voltage of the floating diffusion area FD has been reset, the reset transistor RX may be turned off, the select transistor SX may be turned on based on the select control signal SELS, such that the CDS 151 of the readout circuit 150 may read out a first reset voltage from the first pixel PX11 of the first unit pixel group PG1.

Referring to FIG. 4 and FIG. 7, the first and second transfer transistors TX11 and TX12 of the first unit pixel group PG1 may be sequentially turned on, respectively during a first period D1. The first transfer transistor TX11 may be turned on at a first time point t1, and the second transfer transistor TX12 may be turned on at a second time point t2. As the first transfer transistor TX11 is turned on at the first time point t1, the charges generated by the first photo diode PD11 of the first unit pixel group PG1 may be provided to the floating diffusion area FD. In this case, the readout circuit 150 may generate first_first image data (not shown) based on a pixel voltage corresponding to the amount of the charges provided to the floating diffusion area FD. Furthermore, as the second transfer transistor TX12 is turned on at the second time point t2, the charges generated by the first photo diode PD11 of the first unit pixel group PG1 and the charges generated by the second photo diode PD12 may be summed with each other in the floating diffusion area FD. In this case, the readout circuit 150 may generate first_second image data (not shown) based on a pixel voltage corresponding to the amount of the summed charges in the floating diffusion area FD.

During a second period D2, the first and second transfer transistors TX21 and TX22 of the second unit pixel group PG2 may be sequentially turned on, respectively. The first transfer transistor TX21 may be turned on at a third time point t3, and the second transfer transistor TX22 may be turned on at a fourth time point t4. As the first transfer transistor TX21 is turned on at the third time point t3, the charges generated by the first photodiode PD21 of the second unit pixel group PG2 may be provided to the floating diffusion area FD. In this case, the readout circuit 150 may obtain second_first image data (not shown) based on a pixel voltage corresponding to the amount of charges provided to the floating diffusion area FD. Furthermore, as the second transfer transistor TX22 is turned on at the fourth time point t4, the charges generated by the first photo diode PD21 of the second unit pixel group PG2 and the charges generated by the second photo diode PD22 may be summed with each other in the floating diffusion area FD. In this case, the readout circuit 150 may generate second_second image data (not shown) based on a pixel voltage corresponding to an amount of the summed charges in the floating diffusion area FD.

During a third period D3, the first and second transfer transistors TX31 and TX32 of the third unit pixel group PG3 may be sequentially turned on, respectively. The first transfer transistor TX31 may be turned on at a fifth time point t5, and the second transfer transistor TX32 may be turned on at a sixth time point t6. As the first transfer transistor TX31 is turned on at the fifth time point t5, the charges generated by the first photo diode PD31 of the third unit pixel group PG3 may be provided to the floating diffusion area FD. In this case, the readout circuit 150 may generate third_first image data (not shown) based on a pixel voltage corresponding to an amount of the charges provided to the floating diffusion area FD. Furthermore, as the second transfer transistor TX32 is turned on at the sixth time point t6, the charges generated by the first photo diode PD31 of the third unit pixel group PG3 and the charges generated by the third photo diode PD32 may be summed with each other in the floating diffusion area FD. In this case, the readout circuit 150 may generate third_second image data (not shown) based on a pixel voltage corresponding to the amount of the summed charges in the floating diffusion area FD.

During a fourth period D4, the first and second transfer transistors TX41 and TX42 of the 4th unit pixel group PG4 may be sequentially turned on, respectively. The first transfer transistor TX41 may be turned on at a seventh time point t7, and the second transfer transistor TX42 may be turned on at an eighth time point t8. As the first transfer transistor TX41 is turned on at the seventh time point t7, the charges generated by the first photodiode PD41 of the 4th unit pixel group PG4 may be provided to the floating diffusion area FD. In this case, the readout circuit 150 may generate fourth_first image data (not shown) based on a pixel voltage corresponding to an amount of charges provided to the floating diffusion area FD. As the second transfer transistor TX42 is turned on at the eighth time point t8, the charges generated by the first photodiode PD41 of the fourth unit pixel group PG4 and the charges generated by the second photodiode PD42 may be summed with each other in the floating diffusion area FD. In this case, the readout circuit 150 may generate fourth_second image data (not shown) based on a pixel voltage corresponding to an amount of the summed charges in the floating diffusion area FD.

Although not specifically illustrated, the image sensor may obtain image data from the pixels PX of the second pixel group PG_2 in the above-described manner, and may obtain image data from the pixels PX of the third pixel group PG_3 in the above-described manner, and may obtain image data from the pixels PX of the fourth pixel group PG_4 in the above-described manner.

FIGS. 8 to 11 are diagrams for illustrating a configuration and an operation of a signal processor of an image sensor according to one or more example embodiments.

Referring to FIG. 8, the signal processor 130 may include a front end processing module 131, an image processing module 1322, and an auto-focusing processing module 1321. Each of the modules as described below may be embodied as a software block executed by a given processor, or as a combination of a dedicated hardware block and a processor.

The image data (e.g., IDT of FIG. 2) may include full image data IDTS generated based on pixel signals from all pixels PX of the first to fourth pixel groups PG_1 to PG_4.

In addition, the image data (e.g., IDT of FIG. 2) may include first image data IDT1 generated based on pixel signals from first pixels PX11, PX21, PX31, and PX41 of each of the first to fourth pixel groups PG_1 to PG_4.

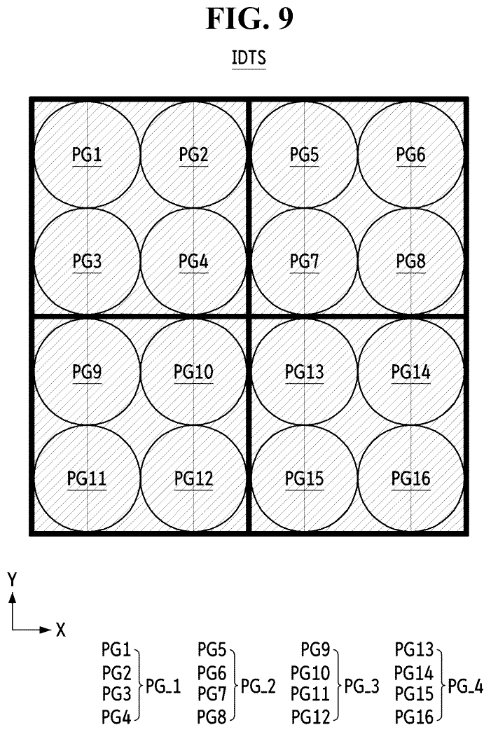

Referring to FIG. 8 and FIG. 9, the front end processing module 131 may receive the image data (e.g., IDT of FIG. 2) output through the readout circuit 150. The front end processing module 131 may receive the full image data IDTS and first image data IDT1 from the readout circuit 150. The front end processing module 131 may perform pre-processing, such as dark level correction, on the received full image data IDTS and the received first image data IDT1, to generate pre-processed first image data IDT1′. However, the disclosure is not limited thereto.

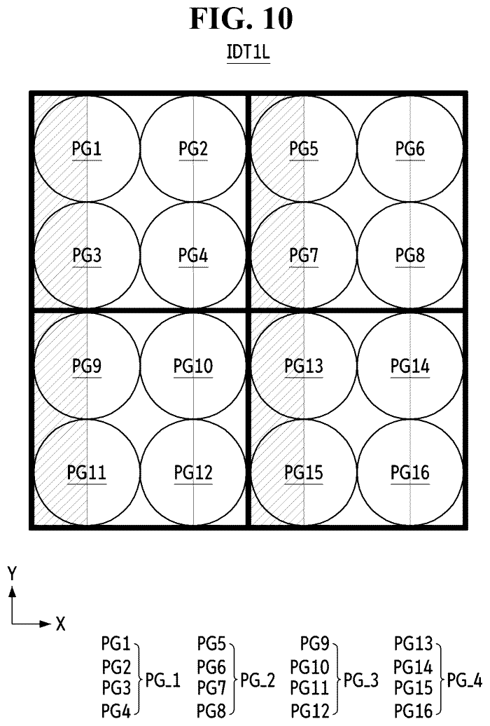

Referring to FIG. 8 and FIG. 10, the auto-focusing processing module 1321 may receive the pre-processed first image data IDT1′ from the front end processing module 131. Although not specifically illustrated, the auto-focusing processing module 1321 may include a sampling and binning module. The auto-focusing processing module 1321 may generate second image data IDT1L based on the first image data IDT1 (or the pre-processed first image data IDT1′). The second image data IDT1L may be image data generated by sampling pixel data corresponding to the left pixels PX11 and PX31 among the first pixels PX11, PX21, PX31, and PX41 of each of the first to fourth pixel groups PG_1 to PG_4. In other words, the pixel data corresponding to the left pixels PX11 and PX31 may be data corresponding to the pixels adjacent to the first partitioning wall structure 250A as described above.

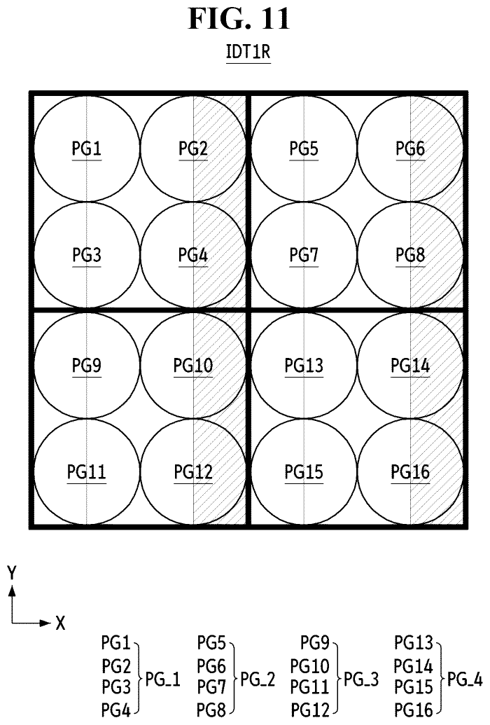

Furthermore, referring to FIG. 8 and FIG. 11, the auto-focusing processing module 1321 may generate third image data IDT1R based on the first image data IDT1 (or the pre-processed first image data IDT1′) and the second image data IDT1L. The third image data IDT1R may be image data generated by sampling pixel data corresponding to the right pixels PX22 and PX42 among the second pixels PX12, PX22, PX32, and PX42 of each of the first to fourth pixel groups PG_1 to PG_4. In other words, the pixel data corresponding to the right pixels PX22 and PX42 may be data corresponding to pixels spaced apart from the first partitioning wall structure 250A as described above.

Referring to FIG. 8, the auto-focusing processing module 1321 may generate respective gray images of the second image data IDT1L and the third image data IDT1R. The generated images may be provided to the processor 12 via a data transfer line based on a mobile industry processor interface (MIPI) 121 and may be used for auto-focusing.

The image processing module 1322 may receive the pre-processed full image data IDTS′ from the front end processing module 131. The image processing module 1322 may generate an image including color information on the full image data IDTS. The generated image may be provided to the processor 12 via the data transfer line based on the MIPI 121 and used for auto-focusing.

FIGS. 12 to 14 are diagrams for illustrating a configuration and an operation of a signal processor of an image sensor according to one or more example embodiments. For the convenience of description, contents duplicate with those as described above with reference to FIGS. 1 to 11 are briefly described or descriptions thereof are omitted.

Referring to FIG. 12, in each of the first and fourth pixel groups PG_1 and PG_4, two pixels PX sharing one micro lens 280 are arranged adjacently to each other in the first direction X. In each of the second and third pixel groups PG_2 and PG_3, two pixels PX sharing one micro lens 280 are arranged adjacently to each other in the second direction Y.

In each of the first and fourth pixel groups PG_1 and PG_4, respective long sides of the two pixels PX sharing one micro lens 280 extend in the second direction Y. In each of the second and third pixel groups PG_2 and PG_3, respective long sides of the two pixels PX sharing one micro lens 280 extend in the first direction X.

Referring to FIG. 8 and FIG. 12, the image data (e.g., IDT of FIG. 2) may include the full image data IDTS generated based on pixel signals from all pixels PX of the first to fourth pixel groups PG_1 to PG_4. In addition, the image data (e.g., IDT of FIG. 2) may include the first image data IDT1 generated based on the pixel signals from the first pixels PX11, PX21, PX31, and PX41 of each of the first to fourth pixel groups PG_1 to PG_4.

Referring to FIG. 8 and FIG. 12, the front end processing module 131 may receive the image data (e.g., IDT of FIG. 2) output through the readout circuit 150. The front end processing module 131 may receive the full image data IDTS and the first image data IDT1. The front end processing module 131 may perform pre-processing, such as dark correction, on the received full image data IDTS and the received first image data IDT1, to generate the pre-processed first image data IDT1′. However, the disclosure is not limited thereto.

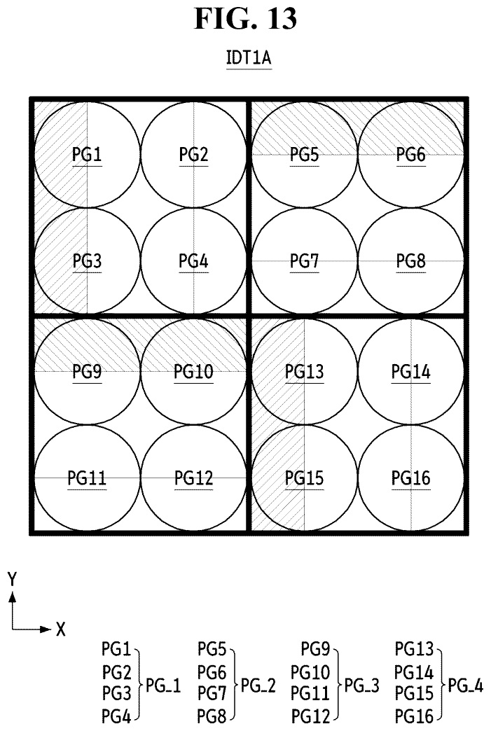

Referring to FIG. 8 and FIG. 13, the auto-focusing processing module 1321 may receive the pre-processed first image data IDT1′ from the front end processing module 131. Although not specifically illustrated, the auto-focusing processing module 1321 may include a sampling and binning module. The auto-focusing processing module 1321 may generate the second image data IDT1A based on the first image data IDT1 (or the pre-processed first image data IDT1′). The second image data IDT1A may be image data generated by sampling pixel data corresponding to left pixels PX11 and PX31 of each of the first and fourth pixel groups PG_1 and PG_4 and upper pixels PX11 and PX21 of each of the second and third pixel groups PG_2 and PG_3.

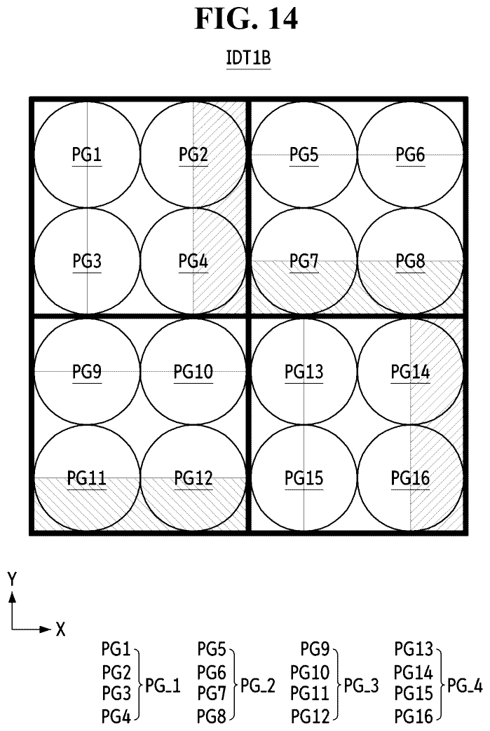

Furthermore, referring to FIG. 8 and FIG. 14, the auto-focusing processing module 1321 may generate the third image data IDT1B based on the first image data IDT1 (or the pre-processed first image data IDT1′) and the second image data IDT1L. The third image data IDT1B may be image data generated by sampling pixel data corresponding to the right pixels PX22 and PX42 of each of the first and fourth pixel groups PG_1 and PG_4 and the lower pixels PX32 and PX42 of each of the second and third pixel groups PG_2 and PG_3.

The auto-focusing processing module 1321 may generate respective gray images of the second image data IDT1A and the third image data IDT1B. The generated images may be provided to the processor 12 via the data transfer line based on the MIPI 121 and used for auto-focusing.

The image processing module 1322 may receive the pre-processed full image data IDTS′ from the front end processing module 131. The image processing module 1322 may generate an image including color information on the full image data IDTS. The generated image may be provided to the processor 12 via the data transfer line based on the MIPI (Mobile Industry Processor Interface) 121 and used for auto focusing.

As a pixel structure becomes finer, an extent to which the light incident on the pixel is screened with the partitioning wall structure may be increased. Accordingly, reliability may be lowered when performing the auto focusing using phase data generated based on the pixel signals.

In one or more example embodiments, no partitioning wall structure may be disposed between adjacent ones of the first to fourth unit pixel groups PG1 to PG4, between adjacent ones of the fifth to eighth unit pixel groups PG5 to PG8, between adjacent ones of the ninth to twelfth unit pixel groups PG9 to PG12, and between adjacent ones of the thirteenth to sixteenth unit pixel groups PG13 to PG16. Alternatively, the partitioning wall structure having a smaller height may be disposed between adjacent ones of the first to fourth unit pixel groups PG1 to PG4, between adjacent ones of the fifth to eighth unit pixel groups PG5 to PG8, between adjacent ones of the ninth to twelfth unit pixel groups PG9 to PG12, and between adjacent ones of the thirteenth to sixteenth unit pixel groups PG13 to PG16. The image sensor in accordance with one or more example embodiments may perform sampling on pixels adjacent to an area where the partitioning wall structure is disposed. That is, the sampling may be performed on the pixels excluding the pixels adjacent to the area where the partitioning wall structure is not disposed or the area where the partitioning wall structure with the smaller height is disposed, such that the auto-focusing may be performed more reliably.

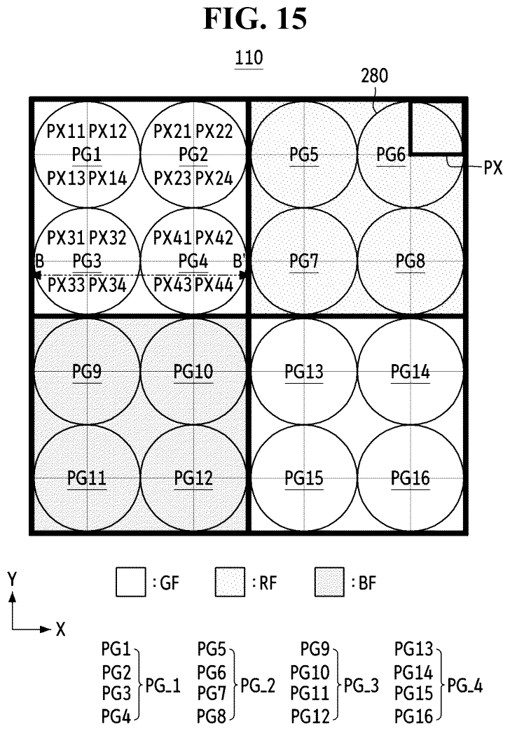

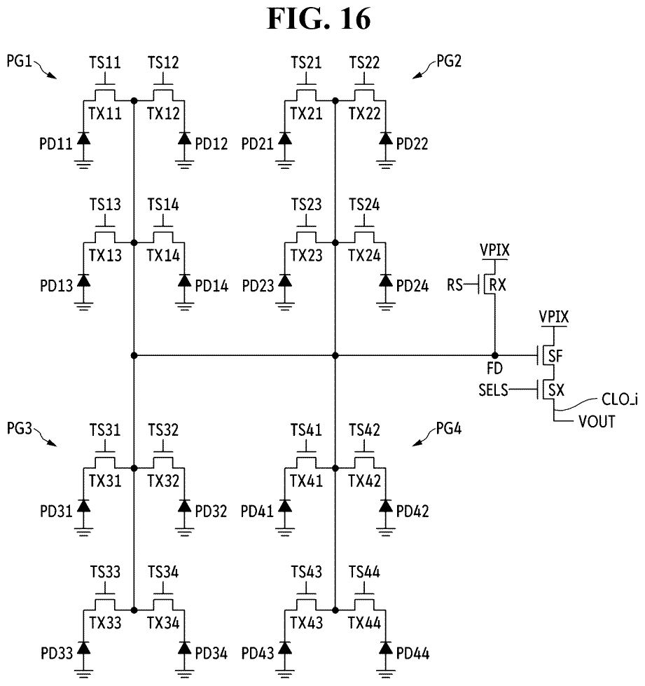

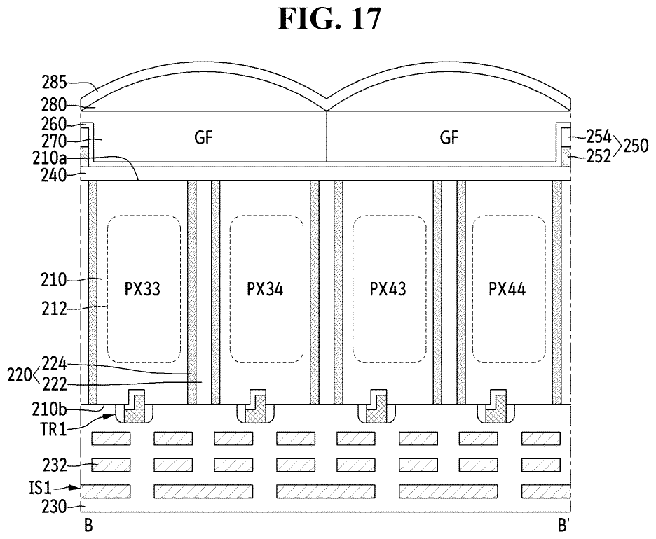

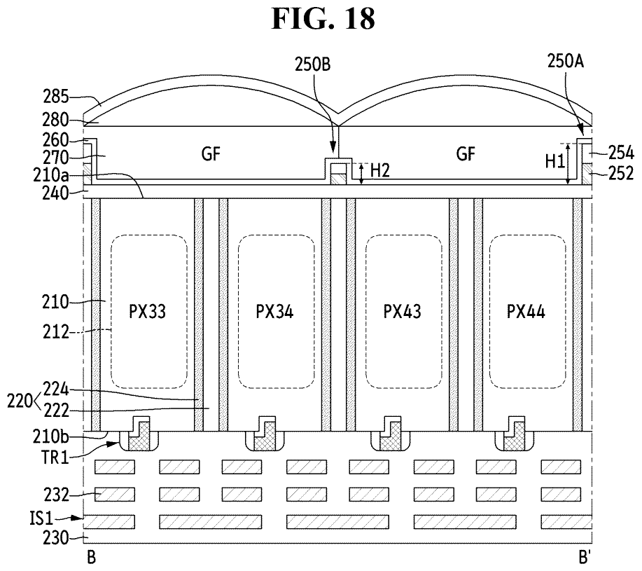

FIG. 15 is a diagram for illustrating a pixel array of an image sensor according to one or more example embodiments. FIG. 16 is an example circuit diagram of the first pixel group of FIG. 15. FIG. 17 is a cross-sectional view taken along a line B-B′ of FIG. 15. FIG. 18 is a diagram for illustrating an image sensor according to one or more example embodiments, and is a diagram corresponding to FIG. 17.

For reference, FIG. 15 shows an example of a portion of the pixel array 110 of FIG. 2. For convenience of description, contents duplicate with those as described above with reference to FIGS. 1 to 14 are briefly described or descriptions thereof are omitted.

Referring to FIG. 15, the pixel array 110 may include a plurality of pixels PX arranged along the first direction X and the second direction Y. Each of the first to sixteenth unit pixel groups PG1 to PG16 may include four pixels PX that share one micro lens 280 with each other. The first to sixteenth unit pixel groups PG1 to PG16 may include 16 different micro lenses 280, respectively. Each of the plurality of pixels PX included in the pixel array 110 may be capable of performing the AF function.

In each of the first to fourth pixel groups PG_1 to PG_4, four pixels PX sharing one micro lens 280 may be arranged adjacently to each other in the first and second directions X and Y.

The description about the first pixel group PG_1 may be equally applied to each of the second to fourth pixel groups PG_2 to PG_4.

Although FIG. 16 illustrates an embodiment in which pixels included in the first to fourth unit pixel groups PG1 to PG4 share the floating diffusion area FD with each other, the disclosure is not limited thereto.

Referring to FIG. 15 and FIG. 16, a first pixel PX11 of the first unit pixel group PG1 may include a first photo diode PD11 and a first transfer transistor TX11, and a second pixel PX12 of the first unit pixel group PG1 may include a second photo diode PD12 and a second transfer transistor TX12. A third pixel PX13 of the first unit pixel group PG1 may include a third photo diode PD13 and a third transfer transistor TX13. A fourth pixel PX14 of the first unit pixel group PG1 may include a fourth photo diode PD14 and a fourth transfer transistor TX14.

A first pixel PX21 of the second unit pixel group PG2 may include a first photo diode PD21 and a first transfer transistor TX21, and a second pixel PX22 of the second unit pixel group PG2 may include a second photo diode PD22 and a second transfer transistor TX22. A third pixel PX23 of the second unit pixel group PG2 may include a third photo diode PD23 and a third transfer transistor TX23, and a fourth pixel PX24 of the second unit pixel group PG2 may include a fourth photo diode PD24 and a fourth transfer transistor TX24.

A first pixel PX31 of the third unit pixel group PG3 may include a first photo diode PD31 and a first transfer transistor TX31, and a second pixel PX32 of the third unit pixel group PG3 may include a second photo diode PD32 and a second transfer transistor TX32. A third pixel PX33 of the third unit pixel group PG3 may include a third photo diode PD33 and a third transfer transistor TX33, and a fourth pixel PX34 of the third unit pixel group PG3 may include a fourth photo diode PD34 and a fourth transfer transistor TX34.

A first pixel PX41 of the fourth unit pixel group PG4 may include a first photo diode PD41 and a first transfer transistor TX41, and a second pixel PX42 of the fourth unit pixel group PG4 may include a second photo diode PD42 and a second transfer transistor TX42. A third pixel PX43 of the fourth unit pixel group PG4 may include a third photo diode PD43 and a third transfer transistor TX43, and a fourth pixel PX44 of the fourth unit pixel group PG4 may include a fourth photo diode PD44 and a fourth transfer transistor TX44.

Each of the first to fourth photodiodes PD11 to PD 14 of the first unit pixel group PG1, the first to fourth photodiodes PD21 to PD24 of the second unit pixel group PG2, the first to fourth photodiodes PD31 to PD34 of the third unit pixel group PG3, and the first to fourth photodiodes PD41 to PD44 of the fourth unit pixel group PG4 may be embodied as the photoelectric conversion element that generates the photoelectric charges that varies depending on the intensity of the light.

For example, each of the first to fourth photodiodes PD11 to PD14 of the first unit pixel group PG1, each of the first to fourth photodiodes PD21 to PD24 of the second unit pixel group PG2, each of the first to fourth photodiodes PD31 to PD34 of the third unit pixel group PG3, and each of the first to fourth photodiodes PD41 to PD44 of the fourth unit pixel group PG4 may be embodied as a P-N junction diode, and may generate charges, that is, electrons as negative charges, and holes as the positive charges in proportion to the amount of incident light thereto.

Each of the first to fourth transfer transistors TX11 to TX14 of the first unit pixel group PG1 may transfer the generated photocharges to the floating diffusion area FD in response to a corresponding transfer control signal (e.g., one of TS11 to TS14). Each of the first to fourth transfer transistors TX21 to TX24 of the second unit pixel group PG2 may transfer the generated photocharges to the floating diffusion area FD in response to a corresponding transfer control signal (e.g., one of TS21 to TS24). Each of the first to fourth transfer transistors TX31 to TX34 of the third unit pixel group PG3 may transfer the generated photocharges to the floating diffusion area FD in response to a corresponding transfer control signal (e.g., one of TS31 to TS34). Each of the first to fourth transfer transistors TX41 to TX44 of the fourth unit pixel group PG4 may transfer the generated photocharges to the floating diffusion area FD in response to a corresponding transfer control signal (e.g., one of TS41 to TS44).

The first to fourth unit pixel groups PG1 to PG4 may share the floating diffusion area FD, the select transistor SX, the source follower SF, and the reset transistor RX. However, in an embodiment, unlike as shown in FIG. 16, at least one of the select transistor SX, the source follower SF, and the reset transistor RX may be omitted. The pixels included in the first to fourth unit pixel groups PG1 to PG4 may output the pixel signal VOUT to the same column output line CL0_i. In this regard, the i-th column output line CLO_i (where i is an integer greater than or equal to 0 and smaller than n-1) may be, for example, one of the first to n-th column output lines (CLO_0 to CLO_n-1 of FIG. 2).

The reset transistor RX may periodically reset charges accumulated in the floating diffusion area FD. The source electrode of the reset transistor RX may be electrically connected to the floating diffusion area FD, and the drain electrode thereof may be electrically connected to the power supply voltage VPIX. When the reset transistor RX is turned on based on the reset control signal RS, the power supply voltage VPIX electrically connected to the drain electrode of the reset transistor RX may be transferred to the floating diffusion area FD. When the reset transistor RX has been turned on, the charges accumulated in the floating diffusion area FD may be discharged, such that the floating diffusion area FD may be reset.

The source follower SF may be controlled based on an amount of photocharges accumulated in the floating diffusion area FD. The source follower SF may act as a buffer amplifier which may buffer a signal according to the charges charged in the floating diffusion area FD. The source follower SF may amplify the potential change in the floating diffusion area FD and output the amplified potential change as the pixel signal VOUT to the i-th column output line CLO_i.

The drain electrode of the select transistor SX may be electrically connected to the source electrode of the source follower SF. The select transistor SX may output the pixel signal VOUT to the CDS (e.g., 151 in FIG. 2) via the column output line in response to the select signal SELS.

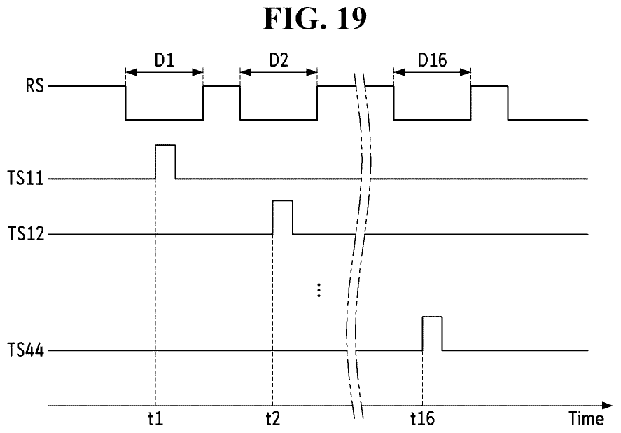

FIG. 19 is a timing diagram for illustrating an operation of an image sensor according to one or more example embodiments. For reference, FIG. 19 is a diagram for illustrating a second operation mode in which sampling and holding, and analog-to-digital converting operations are performed on voltages detected by all unit pixels included in the pixel array of the image sensor.

Referring to FIG. 19, the reset transistor RX may be turned on based on the reset control signal RS to reset the voltage of the floating diffusion area FD. When the voltage of the floating diffusion area FD has been reset, the reset transistor RX is turned off, and the select transistor SX is turned on based on the select control signal SELS, such that the CDS 151 of the readout circuit 150 may readout a first reset voltage from the first pixel PX11 of the first unit pixel group PG1.

When the first reset voltage has been readout, the first transfer transistor TX11 may be turned on at a first time point t1 based on the first transfer control signal TS11, such that the charges of the first photodiode PD11 may migrate to the floating diffusion area FD. The readout circuit 150 may read a first pixel voltage from the first pixel PX11.

The readout circuit 150 may read the first reset voltage and the first pixel voltage during a first period D1, and the readout circuit 150 may obtain image data corresponding to a difference between the first reset voltage and the first pixel voltage.

In the above-described manner, the image sensor may obtain 16 image data corresponding to each of the pixels PX11 to PX44 of each of the first to fourth unit pixel groups PG1 to PG4. That is, using the readout circuit 150, the on/off timings of the transfer transistors TX11 to TX44 of each of the first to fourth unit pixel groups PG1 to PG4 may be controlled to be different from each other, and image data corresponding to each of the pixels PX11 to PX44 may be obtained.

Furthermore, in the above-described manner, the image sensor may obtain image data corresponding to each of the pixels PX of the second pixel group PG_2, obtain image data corresponding to each of the pixels PX of the third pixel group PG_3, and obtain image data corresponding to each of the pixels PX of the fourth pixel group PG_4.

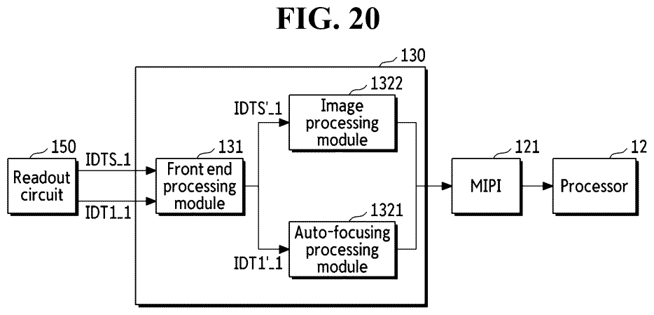

FIGS. 20 to 23 are diagrams for illustrating a configuration and an operation of a signal processor of an image sensor according to one or more example embodiments. For the convenience of description, contents duplicate with those as described above with reference to FIGS. 1 to 19 are briefly described or descriptions thereof are omitted.

The image data (e.g., IDT of FIG. 2) may include full image data IDTS_1 generated based on pixel voltages from all pixels PX of the first to fourth pixel groups PG_1 to PG_4. In addition, the image data (e.g., IDT of FIG. 2) may include first image data IDT1_1 generated based on the pixel voltages from the first pixels PX11, PX21, PX31, and PX41 and the third pixels PX13, PX23, PX33, PX43 of each of the first to fourth pixel groups PG_1 to PG_4.

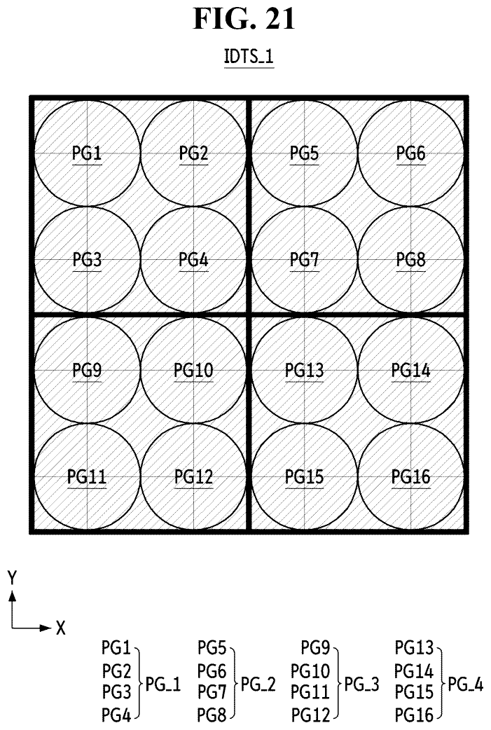

Referring to FIG. 20 and FIG. 21, the front end processing module 131 may receive the image data (e.g., IDT of FIG. 2) output through the readout circuit 150. The front end processing module 131 may receive the full image data IDTS_1 and the first image data IDT1_1. The front end processing module 131 may perform pre-processing, such as dark level correction, on the received full image data IDTS_1 and the received first image data IDT1_1, to generate pre-processed first image data IDT1′_1. However, the disclosure is not limited thereto.

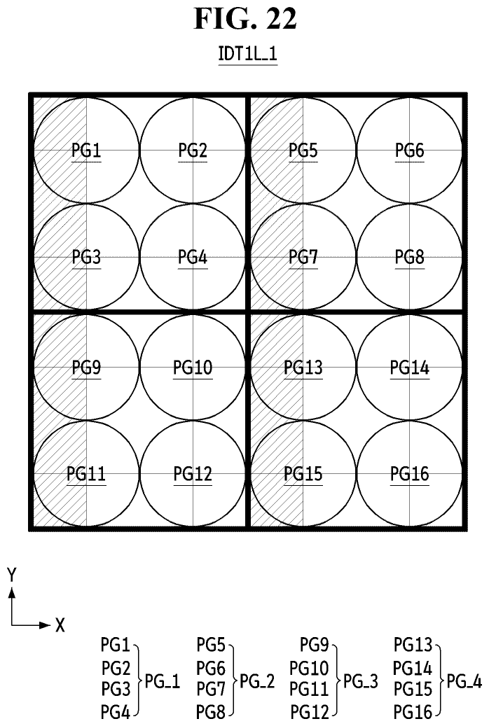

Referring to FIG. 20 and FIG. 22, the auto-focusing processing module 1321 may receive the pre-processed first image data IDT1 ′_1 from the front end processing module 131. Although not specifically illustrated, the auto-focusing processing module 1321 may include a sampling and binning module. The auto-focusing processing module 1321 may generate second image data IDT1L_1 based on the first image data IDT1_1 (or the pre-processed first image data IDT1′_1). The second image data IDT1L_1 may be image data generated by sampling pixel data corresponding to left pixels PX11, PX13, PX31, and PX33 among the first pixels PX11, PX21, PX31, and PX41 and the third pixels PX13, PX23, PX33, and PX43 of each of the first to fourth pixel groups PG_1 to PG_4.

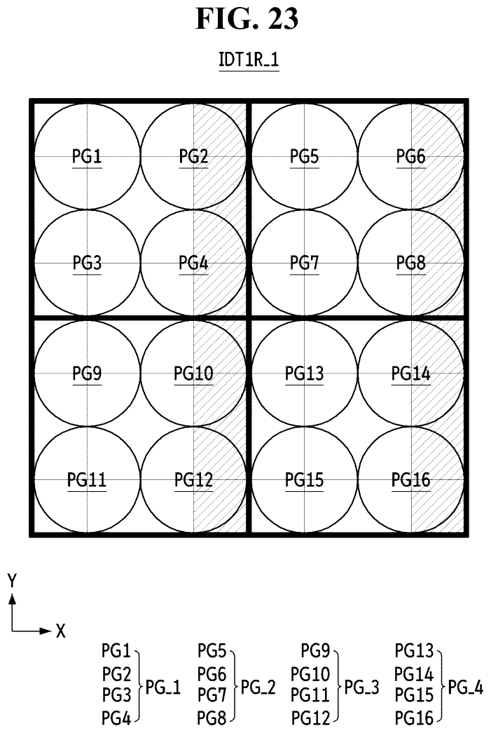

Furthermore, referring to FIG. 20 and FIG. 23, the auto-focusing processing module 1321 may generate third image data IDT1R_1 based on the first image data IDT1_1 (or the pre-processed first image data IDT1′_1) and the second image data IDT1L_1. The third image data IDT1R_1 may be image data generated by sampling pixel data corresponding to right pixels PX22, PX24, PX42, and PX44 among the second pixels PX12, PX22, PX32, and PX42 and the fourth pixels PX14, PX24, PX34, and PX44 of each of the first to fourth pixel groups PG_1 to PG_4.

Referring to FIG. 20, the auto-focusing processing module 1321 may generate respective gray images of the second image data IDT1L_1 and the third image data IDT1R_1. The generated images may be provided to the processor 12 via the data transfer line based on the MIPI 121 and used for auto-focusing.

The image processing module 1322 may receive pre-processed full image data IDTS′_1 from the front end processing module 131. The image processing module 1322 may generate an image including color information on the full image data IDTS_1. The generated image may be provided to the processor 12 via the data transfer line based on the MIPI (Mobile Industry Processor Interface) 121 and used for auto-focusing.

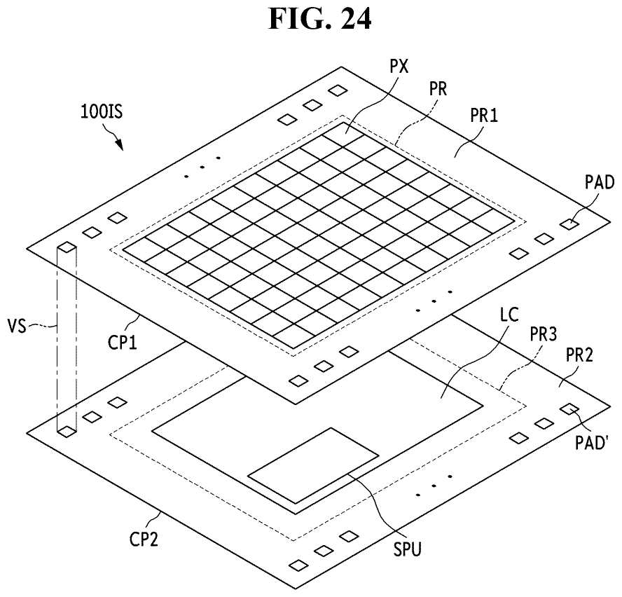

FIG. 24 is a schematic diagram showing an image sensor according to one or more example embodiments.

An image sensor 100IS may be a stack type image sensor including a first chip CP1 and a second chip CP2 that are stacked in a vertical direction. The image sensor 100IS may be embodied as the image sensor 100 as described in FIG. 2. The image sensor 100IS of FIG. 24 is illustrated as having a structure in which two chips are stacked. However, the disclosure is not limited thereto, and the image sensor 100IS may have a structure in which three chips are stacked.

The first chip CP1 may include a pixel area PR and a pad area PR1, and the second chip CP2 may include a peripheral circuit area PR3 and a lower pad area PR2. A pixel array in which a plurality of pixels PX are arranged may be formed in the pixel area PR, and may include the pixel array 110 as described in FIG. 2.

The first chip CP1 may include the partitioning wall structures (e.g., 250A of FIG. 3) which are disposed in a peripheral area of each of the first to fourth pixel groups (e.g., PG_1 to PG_4 of FIG. 3) and extend in the second direction (e.g., Y of FIG. 3) and are spaced apart from each other in the first direction (e.g., X of FIG. 3).

The peripheral circuit area PR3 of the second chip CP2 may include a logic circuit block LC and may include a plurality of transistors. The peripheral circuit area PR3 may provide a predetermined signal to each of the plurality of pixels PX included in the pixel area PR and may read out a pixel signal output from each of the plurality of pixels PX. The readout circuit (e.g., 150 of FIG. 2) may be disposed in the peripheral circuit area PR3. The logic circuit block LC may include a signal processor SPU. The signal processor SPU may correspond to the signal processor (e.g., 130 of FIG. 2).

The lower pad area PR2 of the second chip CP2 may include a lower conductive pad PAD′. The lower conductive pad PAD′ may include lower conductive pads PAD′, each pad PAD′ corresponding to each conductive pad PAD. The lower conductive pad PAD′ may be electrically connected to the conductive pad PAD of the first chip CP1 via a via structure VS.

At least one of the components, elements, modules or units (collectively “components” in this paragraph) represented by a block in the drawings, may be embodied as various numbers of hardware, software and/or firmware structures that execute respective functions described above, according to an example embodiment. For example, at least one of these components may use a direct circuit structure, such as a memory, a processor, a logic circuit, a look-up table, etc. that may execute the respective functions through controls of one or more microprocessors or other control apparatuses. Also, at least one of these components may be specifically embodied by a module, a program, or a part of code, which contains one or more executable instructions for performing specified logic functions, and executed by one or more microprocessors or other control apparatuses. Further, at least one of these components may include or may be implemented by a processor such as a central processing unit (CPU) that performs the respective functions, a microprocessor, or the like. Two or more of these components may be combined into one single component which performs all operations or functions of the combined two or more components. Also, at least part of functions of at least one of these components may be performed by another of these components. Further, although a bus is not illustrated in the above block diagrams, communication between the components may be performed through the bus. Functional aspects of the above example embodiments may be implemented in algorithms that execute on one or more processors. Furthermore, the components represented by a block or processing steps may employ any number of related art techniques for electronics configuration, signal processing and/or control, data processing and the like.

Although example embodiments of the disclosure have been described with reference to the accompanying drawings, the disclosure is not limited to the above embodiments, but may be implemented in various different forms. A person skilled in the art would appreciate that the disclosure may be practiced in other concrete forms without changing the technical spirit or essential characteristics of the disclosure. Therefore, it should be appreciated that the embodiments as described above is not restrictive but illustrative in all respects.

What is claimed is:

1. An image sensor comprising:
a pixel array including a plurality of pixel groups having different color filters, wherein a plurality of micro lenses are respectively arranged in the plurality of pixel groups, wherein each of the plurality of pixel groups includes a plurality of pixels arranged in row and columns;
a readout circuit configured to readout a pixel signal output from the pixel array and generate image data based on the readout pixel signal; and
a signal processor configured to receive and process the image data,
wherein each of the plurality of pixel groups includes a plurality of unit pixel groups, wherein each of the plurality of unit pixel groups includes a first pixel and a second pixel sharing one micro lens of the plurality of micro lenses,
wherein the image data includes:
first image data generated based on pixel signals of respective first pixels and respective second pixels of the plurality of unit pixel groups; and
second image data generated based on pixel signals of the respective first pixels of the plurality of unit pixel groups,
wherein the respective first pixels of the plurality of unit pixel groups include:
a first pixel of a first unit pixel group and a first pixel of a third unit pixel group arranged in a first column and including different micro lenses; and
a first pixel of a second unit pixel group and a first pixel of a fourth unit pixel group arranged in a second column and including different micro lenses, and
wherein the signal processor is configured to generate third image data based on pixel signals of first pixels of the first unit pixel group and the third unit pixel group, excluding pixel signals of first pixels of the second unit pixel group and the fourth unit pixel group.

2. The image sensor of claim 1, wherein the signal processor is further configured to:
receive the first image data and the second image data from the readout circuit and pre-process the first image data and the second image data; and
receive the pre-processed second image data and generate the third image data, based on the pre-processed second image data.

3. The image sensor of claim 2, wherein the signal processor is further configured to generate a gray image of the third image data, and
wherein the signal processor is further configured to, based on the pre-processed first image data, generate an image including color information on the first image data.

4. The image sensor of claim 1, wherein the respective second pixels include:
a second pixel of the first unit pixel group and a second pixel of the third unit pixel group arranged in the first column and including different micro lenses; and
a second pixel of the second unit pixel group and a second pixel of the fourth unit pixel group arranged in the second column and including different micro lenses,
wherein the signal processor is further configured to generate fourth image data based on pixel signals of second pixels of the first unit pixel group and the third unit pixel group, excluding pixel signals of second pixels of the second unit pixel group and the fourth unit pixel group.

5. The image sensor of claim 1, wherein the plurality of pixels included in each of the plurality of unit pixel groups share a floating diffusion area.

6. The image sensor of claim 1, wherein each of the first unit pixel group, the second unit pixel group, the third unit pixel group, and the fourth unit pixel group includes two pixels sharing one micro lens.

7. The image sensor of claim 1, wherein each of the plurality of unit pixel groups further includes third and fourth pixels sharing another micro lens of the plurality of micro lenses.

8. The image sensor of claim 1, wherein the plurality of pixel groups include a first pixel group having a first color filter, a second pixel group having a second color filter, a third pixel group having a third color filter, and a fourth pixel group having a fourth color filter,
wherein the first pixel group includes a plurality of first unit pixel groups, each of the plurality of first unit pixel groups including two pixels sharing one micro lens,
wherein the second pixel group includes a plurality of second unit pixel groups, each of the plurality of second unit pixel groups including two pixels sharing one micro lens,
wherein the third pixel group includes a plurality of third unit pixel groups, each of the plurality of third unit pixel groups including two pixels sharing one micro lens, and
wherein the fourth pixel group includes a plurality of fourth unit pixel groups, each of the plurality of fourth unit pixel groups including two pixels sharing one micro lens.

9. The image sensor of claim 8, further comprising:
first partitioning wall structures disposed between adjacent ones of the first to the fourth pixel groups in a plan view of the image sensor; and
second partitioning wall structures disposed between adjacent ones of the plurality of first unit pixel groups, disposed between adjacent ones of the plurality of second unit pixel groups, disposed between adjacent ones of the plurality of third unit pixel groups, and disposed between adjacent ones of the plurality of fourth unit pixel groups in the plan view of the image sensor,
wherein a height of a second partitioning wall structure is smaller than a height of a first partitioning wall structure.

10. The image sensor of claim 8, further comprising partitioning wall structures disposed between adjacent ones of the first to the fourth pixel groups in a plan view of the image sensor,
wherein a partitioning wall structure is absent between adjacent ones of the plurality of first unit pixel groups, absent between adjacent ones of the plurality of second unit pixel groups, absent between adjacent ones of the plurality of third unit pixel groups, and absent between adjacent ones of the plurality of fourth unit pixel groups in the plan view of the image sensor.

11. The image sensor of claim 8, wherein the plurality of pixels in each of the first to the fourth pixel groups are arranged in a first direction and a second direction intersecting the first direction,
wherein in each of the first to the fourth pixel groups, two pixels sharing one micro lens are arranged adjacently to each other in the first direction, and
wherein in each of the second and the third pixel groups, two pixels sharing one micro lens are arranged adjacently to each other in the second direction.

12. An image sensor comprising:
a first pixel group having a first color filter, a second pixel group having a second color filter, a third pixel group having a third color filter, and a fourth pixel group having a fourth color filter, wherein each of the first to the fourth pixel groups includes a plurality of pixels arranged in a first direction and a second direction intersecting the first direction, wherein each of the first to the fourth pixel groups includes a plurality of unit pixel groups;
a readout circuit configured to readout pixel signals output from the plurality of pixels and generate pixel data based on the pixel signals;
a signal processor configured to receive and process the pixel data;
first partitioning wall structures and second partitioning wall structures disposed in a peripheral area of each of the first to the fourth pixel groups, wherein the first and the second partitioning wall structures extend in the first direction and are spaced apart from each other in the second direction in a plan view of the image sensor; and
third partitioning wall structures disposed between adjacent ones of the plurality of unit pixel groups included in each of the first to the fourth pixel groups, and extending in the first direction in the plan view of the image sensor,
wherein the first pixel group includes first pixels adjacent to a first partitioning wall structure and arranged in the first direction in the plan view of the image sensor,
wherein the second pixel group includes first pixels adjacent to a second partitioning wall structure and arranged in the first direction in the plan view of the image sensor,
wherein a height of the first partitioning wall structure and a height of the second partitioning wall structure are different from a height of a third partitioning wall structure, and
wherein the signal processor is configured to generate first image data obtained by sampling pixel data corresponding to the first pixels of the first pixel group and the first pixels of the second pixel group.

13. The image sensor of claim 12, wherein the first pixel group further includes second pixels spaced apart from the first partitioning wall structure and arranged in the first direction,
wherein the second pixel group further includes second pixels spaced apart from the second partitioning wall structure and arranged in the first direction, and
wherein the signal processor is further configured to generate second image data obtained by sampling pixel data corresponding to the second pixels of the first pixel group and the second pixels of the second pixel group.

14. The image sensor of claim 12, wherein each of the height of the first partitioning wall structure and the height of the second partitioning wall structure is greater than the height of the third partitioning wall structure.

15. The image sensor of claim 12, further comprising fourth partitioning wall structures and fifth partitioning wall structures extending in the second direction and spaced apart from each other in the first direction in the plan view of the image sensor,
wherein the first, the second, the fourth, and the fifth partitioning wall structures surround each of the first to the fourth pixel groups in the plan view.

16. The image sensor of claim 12, wherein each of the plurality of unit pixel groups includes two pixels sharing one micro lens.

17. The image sensor of claim 12, wherein each of the plurality of unit pixel groups includes four pixels sharing one micro lens.

18. An image processing device comprising:
a pixel array including a plurality of pixel groups having different color filters, wherein each of the plurality of pixel groups includes a plurality of pixels arranged in a first direction and a second direction intersecting the first direction;
a readout circuit configured to readout a pixel signal output from the pixel array and generate image data based on the readout pixel signal;
a signal processor configured to generate first image data and second image data sampled based on the image data; and
a processor configured to receive data on a phase difference, which is based on the first image data and the second image data, from the signal processor,
wherein each of the plurality of pixel groups includes a plurality of unit pixel groups, wherein each of the plurality of unit pixel groups includes a first pixel and a second pixel sharing one micro lens,
wherein the image data includes:
full image data generated based on pixel signals of first pixels and second pixels of the plurality of unit pixel groups; and
third image data generated based on pixel signals of the first pixels of the plurality of unit pixel groups,
wherein the first pixels of the plurality of unit pixel groups include:
a first pixel of a first unit pixel group and a first pixel of a third unit pixel group arranged in a first column and including different micro lenses; and
a first pixel of a second unit pixel group and a first pixel of a fourth unit pixel group arranged in a second column and including different micro lenses, and
wherein the signal processor is configured to generate the first image data based on pixel signals of the first pixels of the first unit pixel group and the third unit pixel group, excluding pixel signals of the first pixels of the second unit pixel group and the fourth unit pixel group.

19. The image processing device of claim 18, wherein the signal processor is further configured to:
receive the full image data and the third image data from the readout circuit and perform pre-processing on the full image data and the third image data; and
receive the pre-processed third image data and generate the first image data based on the pre-processed third image data.

20. The image processing device of claim 18, wherein the second pixels of the plurality of unit pixel groups include:
a second pixel of the first unit pixel group and a second pixel of the third unit pixel group arranged in the first column and including different micro lenses; and
a second pixel of the second unit pixel group and a second pixel of the fourth unit pixel group arranged in the second column and including different micro lenses,
wherein the signal processor is further configured to generate the second image data based on pixel signals of the second pixels of the first unit pixel group and the third unit pixel group, excluding pixel signals of the second pixels of the second unit pixel group and the fourth unit pixel group.
